(19) United States
(12) Patent Application Publication
(10) Pub. No.: US 2007/0281456 A1
(43) Pub. Date: Dec. 6, 2007

(54) Method of forming line of semiconductor device

(75) Inventors: Tae Kyung Kim, Chungcheongbuk-do (KR); Jik Ho Cho, Kyeongki-do (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Icheon-si (KR)

(21) Appl. No.: 11/593,772

(22) Filed: Nov. 7, 2006

(30) Foreign Application Priority Data
May 30, 2006 (KR) 2006-48598
Sep. 29, 2006 (KR) 2006-95989

(51) Int. Cl. H01L 21/4763

(52) U.S. Cl. 438/592

(57) ABSTRACT

A method of forming a line of a semiconductor device, wherein electrical characteristics of the device can be improved by reducing the resistance of the line. According to the method, an amorphous silicide layer or an amorphous TiSiN layer is formed on a semiconductor substrate in which given structures are formed. A line conductive layer is formed on the amorphous silicide layer or the amorphous TiSiN layer.

### BACKGROUND OF THE INVENTION

1. Field of the Invention

The invention relates, in general, to semiconductor devices and, more particularly, to a method of forming lines of a semiconductor device, in which it can reduce the resistance of the lines.

2. Discussion of Related Art

In general, as the line width of semiconductor devices becomes smaller and the level of integration thereof is increased, a required line width cannot be met by a line formation method employing the conventional Reactive Ion Etch (RIE) process. Accordingly, a line formation method employing the damascene method has been widely used.

In the case of the line formation method employing the damascene method, a line material must be deposited and gap-filled in a pattern region formed in trench and contact forms unlike when the RIE method is used.

In semiconductor devices, tungsten (W) is generally used as a conductive layer for a main line material. In the case of W, WF₆ is used as a deposition gas. Accordingly, it is necessary that a barrier metal layer be deposited using TiN, TaN, TiW, or the like, which has a resistance relatively higher than that of W, before W is formed. In recent years, formation of TiN by a Chemical Vapor Deposition (CVD) method having good step coverage is generally used due to the influence of line miniaturization.

Furthermore, it is common that TiSiₓ for ohmic contact is not formed until the TiN layer is formed, and a Ti layer (i.e., an adhesive layer) is deposited in order to improve adhesion.

It is required that the Ti/TiN layer be deposited to a given thickness or more before W (i.e., the conductive layer for the main line material) is deposited. However, in an actual line structure, the Ti/TiN layer accounts most of the thickness. In particular, the damascene method includes forming the Ti/TiN layer and the W layer in a trench that is already formed, unlike the RIE method. Accordingly, the Ti/TiN layer has a 3D structure. It makes the Ti/TiN layer accounts for most thickness.

Furthermore, as the line structure becomes finer, the Ti/TiN layer accounts for more thickness, thus leading to deposition and gap-fill failure of W (i.e., the conductive layer for the main line material). Accordingly, problems arise because the volume of the conductive layer for the main line material reduces, voids are formed within the conductive layer for the main line material, and so on. As a result, line resistance is increased and, therefore, an electrical characteristic of devices is degraded.

The easiest and most sure method of improving the gap-fill characteristic and the electrical characteristic of the conductive layer for the main line material is to reduce the thickness of the barrier metal layer and, therefore, to reduce the weight of the conductive layer for the main line material. If the thickness of the barrier metal layer is lower than a critical thickness, however, the original purpose of the barrier metal layer is lost; thus results in an increased resistance problem by WF₆ used to deposit W (i.e., the conductive layer for the main line material), a “F attach” problem in which the WF₆ gas infiltrates into the semiconductor substrate, a “W volcano” problem in which a Ti layer and WF₆ react to each other explosively, and so on.

For example, the pitch of the trench must be set to a constant value and the thickness of the barrier metal layer must be set to a critical value or more. Accordingly, there is a need for a method of improving the resistivity of the conductive layer for the main line material itself.

### SUMMARY OF THE INVENTION

Accordingly, the invention addresses the above problems, and provides a method of forming lines of a semiconductor device, in which an amorphous silicide layer or an amorphous TiSiN layer is not formed until a conductive layer for a main line material is formed in order to distribute a nucleus for forming the conductive layer when the nucleus is subsequently generated and also to reduce the resistivity of the conductive layer formed thereon, thereby reducing the resistance of the line.

According to one aspect, the invention provides a method of forming lines of a semiconductor device, including the steps of forming an amorphous silicide layer on a semiconductor substrate, and forming a line conductive layer on the amorphous silicide layer.

The method further includes the steps of, before the amorphous silicide layer is formed, forming an adhesive layer on the semiconductor substrate, and forming a barrier metal layer on the adhesive layer. The adhesive layer is preferably formed of Ti, and the barrier metal layer may be formed using one of TiN, TaN and TiW, for example.

The method further includes the step of forming an ohmic contact layer at the interface of the adhesive layer and the semiconductor substrate after the amorphous silicide layer is formed. The ohmic contact layer is a metal silicide layer formed as metal ions of the adhesive layer and silicon ions of the semiconductor substrate react to each other by a thermal treatment process.

The thermal treatment process for forming the ohmic contact layer is preferably performed by a Rapid Thermal Process (RTP) method at a temperature of 600° C. to 900° C. for 10 seconds to 30 seconds.

The amorphous silicide layer is preferably an amorphous WSiₓ layer. The amorphous WSiₓ layer may be formed using SiH₄ and WF₆ as a source gas.

Meanwhile, the amorphous silicide layer is preferably formed using one of a Chemical Vapor Deposition (CVD) method, an Atomic Layer Deposition (ALD) method, and a Physical Vapor Deposition (PVD) method. In the case where the CVD method is employed, the amorphous silicide layer is preferably formed to a thickness of 80 Å to 150 Å. In the case where the ALD method is employed, the amorphous silicide layer is preferably formed to a thickness of 10 Å to 100 Å.

The line conductive layer is preferably formed by creating a nucleus of W on the amorphous silicide layer or a TiSiN layer and depositing W using H₂ and WF₆ by one of a CVD method and a PVD method.

### BRIEF DESCRIPTION OF THE DRAWINGS

FIG. 1 is a graph illustrating the resistivity Rs of PVD W depending on the thickness of an under layer;

FIGS. 2A to 2D are cross-sectional view illustrating a method of forming a line of a semiconductor device according to a first embodiment of the invention;

FIGS. 3A to 3C are cross-sectional view illustrating a method of forming a line of a semiconductor device according to a second embodiment of the invention; and

FIG. 4 is a graph illustrating a comparison result between the resistivities Rs of lines according to the prior art and the invention.

### DESCRIPTION OF SPECIFIC EMBODIMENTS

Specific embodiments according to the invention are described below with reference to the accompanying drawings.

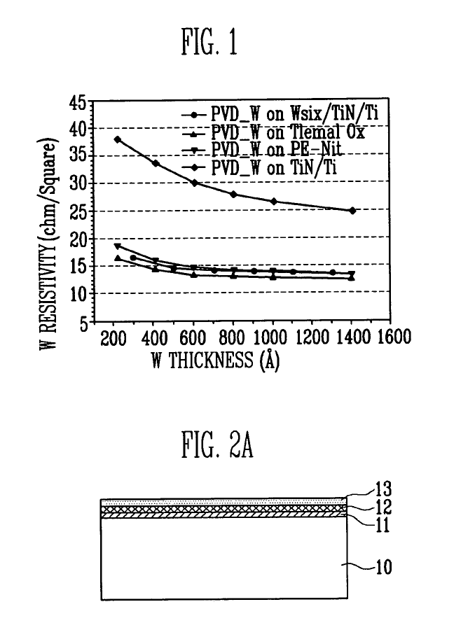

FIG. 1 is a graph illustrating the resistivity (Rs) of PVD tungsten (W) depending on the thickness of an underlayer.

From FIG. 1, it can be seen that a PVD tungsten layer formed on a Ti/TiN layer has a high resistivity value, whereas PVD tungsten layers formed on a thermal oxide layer, a Plasma Enhanced (PE) nitride layer, and a Ti/TiN/WSiₓ layer respectively, have a low resistivity value.

Accordingly, in the invention, an amorphous WSiₓ layer is formed on the Ti/TiN layer in order to distribute a nucleus for generating subsequent W. Furthermore, the grain size of W deposited thereon is increased and a W layer having a low resistivity is formed in order to lower the resistance of a line. In this case, the amorphous TiSiN layer may be used instead of the amorphous WSiₓ layer in order to distribute a nucleus for generating subsequent W.

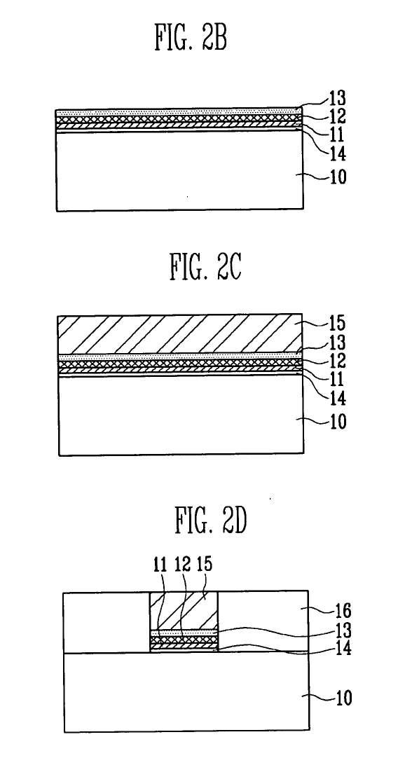

FIGS. 2A to 2D are cross-sectional view illustrating a method of forming a line of a semiconductor device according to a first embodiment of the invention.

Referring to FIG. 2A, an adhesive layer 11, a barrier metal layer 12, and an amorphous silicide layer or an amorphous TiSiN layer 13 are sequentially formed on a semiconductor substrate 10. The adhesive layer 11 is preferably formed using Ti, the barrier metal layer 12 is preferably formed using one of TiN, TaN, and TiW, and the amorphous silicide layer 13 is preferably an amorphous WSiₓ layer. The amorphous WSiₓ layer 13 is preferably formed using SiH₄ and WF₆ as source gases at a temperature of 350° C. to 550° C. by one of a CVD method, an ALD method, and a PVD method, for example. In the case where the CVD method is used, the amorphous WSiₓ layer 13 is preferably formed to a thickness of 80 Å to 150 Å, and in the case where the ALD method is used, the amorphous WSiₓ layer 13 is preferably formed to a thickness of 10 Å to 100 Å.

The amorphous WSiₓ layer 13 serves to distribute when creating a nucleus for subsequent W and increases the grain size of bulk W deposited thereon, thereby reducing the resistivity.

Referring to FIG. 2B, an ohmic contact layer 14 is formed at the interface of the adhesive layer 11 and the semiconductor substrate 10. The ohmic contact layer 14 is preferably formed by a thermal treatment process. If the adhesive layer 11 is formed of titanium (Ti), Ti ions of the adhesive layer 11 and Si ions of the semiconductor substrate 10 are forced to react to each other, thus forming a TiSiₓ layer (i.e., a metal silicide layer). The thermal treatment process is preferably performed according to a Rapid Thermal Process (RTP) method. In this case, a process temperature is preferably set within a range of 600° C. to 900° C. and a process time is preferably set in the range of 10 seconds to 30 seconds.

Referring to FIG. 2C, a line conductive layer 15 is formed on the amorphous silicide layer or the amorphous TiSiN layer 13.

The line conductive layer 15 is formed by creating a nucleus of W on the amorphous silicide layer or the amorphous TiSiN layer 13 and then reflowing H₂ and WF₆ to deposit W. When creating the nucleus of W, the nucleus is distributed on the amorphous silicide layer or the amorphous TiSiN layer 13, and W is therefore deposited around the distributed W nucleus. It is therefore possible to obtain a W layer having a large grain size. The W layer having a large grain size has a resistivity lower than that of a W layer having a small grain size. Accordingly, the resistance of lines can be lowered. The W layer is preferably formed by depositing W by the CVD or PVD method.

Referring to FIG. 2D, the line conductive layer 15, the amorphous silicide layer or the amorphous TiSiN layer 13, the barrier metal layer 12, the adhesive layer 11, and the ohmic contact layer 14 are sequentially patterned by an etch process. An insulating layer 16 is formed on the entire surface. The insulating layer 16 is polished to expose the line conductive layer 15. Accordingly, the line formation process according to a first embodiment of the invention is thereby completed.

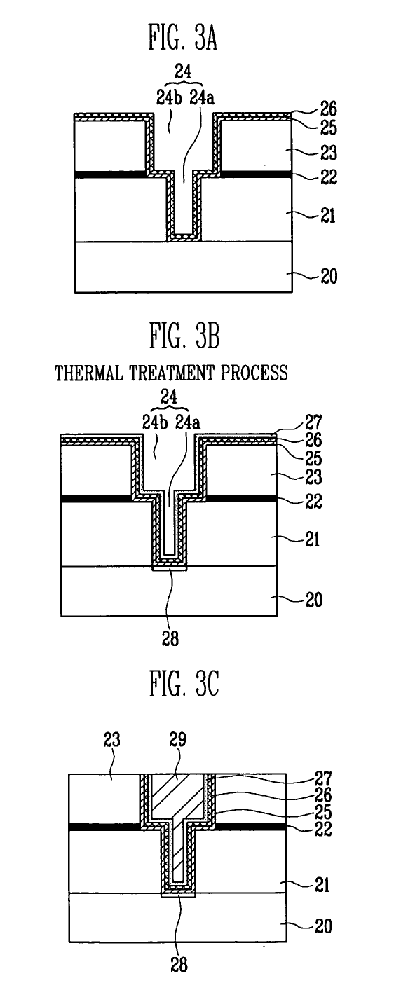

FIGS. 3A to 3C are cross-sectional view illustrating a method of forming a line of a semiconductor device according to a second embodiment of the invention. In this case, a dual damascene process is applied.

Referring to FIG. 3A, a first interlayer insulating layer 21, an etch-stop layer 22 and a second interlayer insulating layer 23 are sequentially formed on a semiconductor substrate 20. A trench 24a is formed in the second interlayer insulating layer 23 and the etch-stop layer 22, and a contact hole 24b is formed in the first interlayer insulating layer 21, thus completing a dual damascene structure 24. The first and second interlayer insulating layers 21 and 23 are preferably formed using an oxide layer. Furthermore, the etch-stop layer 22 is preferably formed using a nitride layer in order to prevent attack on the first interlayer insulating layer 21 at the time of an etch process for forming the trench 24a in the second interlayer insulating layer 23.

An adhesive layer 25, a barrier metal layer 26, and an amorphous silicide layer or the amorphous TiSiN layer 27 are sequentially formed on the entire surface including the dual damascene structure 24.

The adhesive layer 25 is preferably formed using Ti, the barrier metal layer 26 is preferably formed using one of TiN, TaN, and TiW, and the amorphous silicide layer 27 is preferably an amorphous WSiₓ layer. The amorphous WSiₓ layer 27 is preferably formed using SiH₄ and WF₆ as source gases at a temperature of 350° C. to 550° C. by one of a CVD method, an ALD method, and a PVD method, for example. In the case where the CVD method is used, the amorphous WSiₓ layer 27 is preferably formed to a thickness of 80 Å to 150 Å, and in the case where the ALD method is used, the amorphous WSiₓ layer 27 is preferably formed to a thickness of 20 Å to 200 Å.

The amorphous WSiₓ layer 27 serves to distribute when creating a nucleus for subsequent W and increase the grain size of bulk W deposited thereon, thereby reducing the resistivity.

Referring to FIG. 3B, an ohmic contact layer 28 is formed at the interface of the adhesive layer 25 and the semiconductor substrate 20. The ohmic contact layer 28 is preferably formed by a thermal treatment process. If the adhesive layer 25 is formed of titanium (Ti), Ti ions of the adhesive layer 25 and Si ions of the semiconductor substrate 20 are forced to react to each other, thus forming a TiSiₓ layer (i.e., a metal silicide layer). The thermal treatment process is preferably performed according to a RTP method. In this case, a process temperature is preferably set within a range of 600° C. to 900° C. and a process time is preferably set in the range of 20 seconds to 30 seconds.

Referring to FIG. 3C, a line conductive layer 29 is formed on the amorphous silicide layer or the amorphous TiSiN layer 27. The line conductive layer 29 is polished to expose the second interlayer insulating layer 23, thereby forming a line.

The line conductive layer 29 is formed by creating a nucleus of W on the amorphous silicide layer or the amorphous TiSiN layer 27 and then reflowing H₂ and WF₆ to deposit W. When creating the nucleus of W, the nucleus is distributed on the amorphous silicide layer or the amorphous TiSiN layer 27, and W is therefore deposited around the distributed W nucleus. It is therefore possible to obtain a W layer having a large grain size. The W layer having a large grain size has a resistivity lower than that of a W layer having a small grain size. Accordingly, the resistance of lines can be lowered. The W layer is preferably formed by depositing W by the CVD or PVD method. The damascene structure falls short of gap-fill margin. Accordingly, it is preferred that a CVD method with a good step coverage characteristic be used.

The line formation process of the semiconductor device according to a second embodiment of the invention is thereby completed. In the second embodiment as described, the line is formed in the dual damascene structure. However, the second embodiment may be applied to a single damascene structure, a triple damascene structure, or the like.

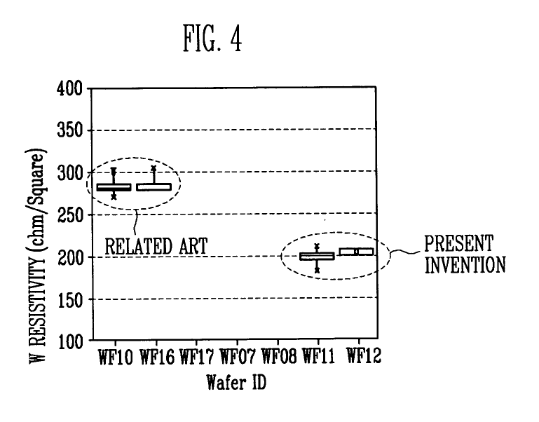

FIG. 4 is a graph illustrating a comparison result between the resistivities Rs of lines according to the prior art and the invention.

From FIG. 4, it can be seen that in the prior art, the resistivity of the line is about 270 ohm/square, whereas in the invention, the resistivity of the line is about 180 ohm/square. Accordingly, the resistivity of the line can be reduced significantly.

As described above, according to the invention, an amorphous silicide layer or an amorphous TiSiN layer is not formed until a conductive layer for a main line material is formed in order to distribute a nucleus for forming the conductive layer when the nucleus is subsequently created and also to reduce the resistivity of the conductive layer formed thereon. Accordingly, since the resistance of the line can be lowered, electrical characteristic of devices can be improved.

Although the foregoing description has been made with reference to various embodiments changes and modifications may be made by those of ordinary skill in the art without departing from the spirit and scope of the invention.

What is claimed is:

1. A method of forming a line of a semiconductor device, the method comprising the steps of:
forming an amorphous silicide layer on a semiconductor substrate; and
forming a line conductive layer on the amorphous silicide layer.

2. The method of claim 1, further comprising the steps of, before forming the amorphous silicide layer,
forming an adhesive layer on the semiconductor substrate; and
forming a barrier metal layer on the adhesive layer.

3. The method of claim 2, wherein the adhesive layer comprises Ti.

4. The method of claim 2, wherein the barrier metal layer comprises at least one of TiN, TaN, and TiW.

5. The method of claim 2, further comprising the step of forming an ohmic contact layer at the interface of the adhesive layer and the semiconductor substrate after forming the amorphous silicide layer.

6. The method of claim 5, comprising forming the ohmic contact layer as a metal silicide layer formed by reacting metal ions of the adhesive layer and silicon ions of the semiconductor substrate by a thermal treatment process.

7. The method of claim 6, wherein the metal silicide layer comprises a titanium silicide layer.

8. The method of claim 6, comprising performing the thermal treatment process at a temperature of 600° C. to 900° C.

9. The method of claim 6, comprising performing the thermal treatment process according to a Rapid Thermal Process (RTP) method.

10. The method of claim 6, comprising performing the thermal treatment process for 10 seconds to 30 seconds.

11. The method of claim 1, wherein the amorphous silicide layer comprises an amorphous WSiₓ layer.

12. The method of claim 11, comprising forming the amorphous WSiₓ layer using SiH₄ and WF₆ as a source gas.

13. The method of claim 1, comprising forming the amorphous silicide layer using one of a Chemical Vapor Deposition (CVD) method, an Atomic Layer Deposition (ALD) method, and a Physical Vapor Deposition (PVD) method.

14. The method of claim 13, comprising employing the CVD method and forming the amorphous silicide layer to a thickness of 80 Å to 150 Å.

15. The method of claim 13, comprising employing the ALD method and forming the amorphous silicide layer to a thickness of 10 Å to 100 Å.

16. The method of claim 1, comprising forming the amorphous silicide layer at a temperature of 350° C. to 500° C.

17. The method of claim 1, wherein the line conductive layer comprises a tungsten (W) layer.

18. The method of claim 1, comprising forming the line conductive layer by creating a nucleus of W on the amorphous silicide layer and depositing W.

19. The method of claim 18, comprising depositing W using H₂ and WF₆.

20. The method of claim 18, comprising depositing W by one of a CVD method and a PVD method.

21. A method of forming a line of a semiconductor device, the method comprising the steps of:
forming an amorphous TiSiN layer on a semiconductor substrate; and
forming a line conductive layer on the amorphous TiSiN layer.

22. The method of claim 21, further comprising the steps of, before forming the amorphous TiSiN layer,
forming an adhesive layer on the semiconductor substrate; and
forming a barrier metal layer on the adhesive layer.

23. The method of claim 22, wherein the adhesive layer comprises Ti.

24. The method of claim 22, wherein the barrier metal layer comprises one of TiN, TaN, and TiW.

25. The method of claim 22, further comprising the step of forming an ohmic contact layer at the interface of the adhesive layer and the semiconductor substrate after forming the amorphous TiSiN layer.

26. The method of claim 25, comprising forming the ohmic contact layer as a metal silicide layer formed by reacting metal ions of the adhesive layer and silicon ions of the semiconductor substrate by a thermal treatment process.

27. The method of claim 26, wherein the metal silicide layer is a titanium silicide layer.

28. The method of claim 26, comprising performing the thermal treatment process at a temperature of 600° C. to 900° C.

29. The method of claim 26, comprising performing the thermal treatment process according to a Rapid Thermal Process (RTP) method.

30. The method of claim 26, comprising performing the thermal treatment process for 10 seconds to 30 seconds.

31. The method of claim 21, wherein the line conductive layer comprises a tungsten (W) layer.

32. The method of claim 21, comprising forming the line conductive layer by creating a nucleus of W on the amorphous TiSiN layer and depositing W.

33. The method of claim 32, comprising depositing W using H₂ and WF₆.

34. The method of claim 32, comprising depositing W by one of a CVD method and a PVD method.
